(19) United States
(12) Patent Application Publication
(10) Pub. No.: US 2025/0259829 A1
(43) Pub. Date: Aug. 14, 2025

(54) COMPONENT, SYSTEM, AND METHOD FOR IMPROVED FORELINE CLEANING

(71) Applicant: Applied Materials, Inc., Santa Clara, CA (US)

(72) Inventors: Daemian Raj Benjamin RAJ, Santa Clara, CA (US); Nuo WANG, Santa Clara, CA (US); Zaoyuan GE, Santa Clara, CA (US); Sungwon HA, Palo Alto, CA (US); Bharati NEELAMRAJU, Sunnyvale, CA (US); Prashant Kumar KULSHRESHTHA, San Jose, CA (US); Jennifer Y. SUN, Mountain View, CA (US); Prasath POOMANI, Dharmapuri (IN); Prakash HUDEDA, Bengaluru (IN)

(21) Appl. No.: 19/054,159

(22) Filed: Feb. 14, 2025

Related U.S. Application Data
(60) Provisional application No. 63/553,485, filed on Feb. 14, 2024.

(51) Int. Cl. H01J 37/32

(52) U.S. Cl. CPC H01J 37/32862; H01J 37/32834; H01J 2237/335

(57) ABSTRACT

A component, system, and method for improved foreline cleaning of semiconductor chambers and components are disclosed herein. In one example, a processing chamber component includes a foreline constructed from stainless steel having a circular cross sectional shape and an inner surface. The foreline further includes a first end configured to couple to a processing chamber, a second end configured to couple to a valve, and a coating disposed within the inner surface of the foreline, the coating having a thickness between about 150 nanometers and about 525 nanometer. Further, the first end includes a first flange, the second end comprises a second flange, wherein the first end and the second end are coupled by a bend. Further, the coating has properties configured to reduce depositions within the foreline.

### RELATED APPLICATIONS

This application claims benefit of and priority to U.S. Provisional Application No. 63/553,485 filed Feb. 14, 2024, which is herein incorporated in its entirety by reference for all purposes.

### BACKGROUND

### Field

Embodiments of the present disclosure generally relate to improved foreline cleaning of semiconductor chamber components, and more specifically, coatings on a foreline conduit of a semiconductor processing chamber to improve foreline cleaning.

### Description of the Related Art

In semiconductor manufacturing, integrated circuit (IC) are formed on semiconductor substrates through various manufacturing steps, including etching, deposition, ion implantation, and annealing, performed in processing chambers. During some of these manufacturing steps, process gases and processing by-products are pumped out of the processing chambers into an exhaust system through a chamber foreline. Deposits may undesirably form in the chamber foreline and other downstream equipment. These undesired deposits may result in diminished performance of the exhaust system and/or exhaust component damage.

To reduce the buildup of undesired depositions within the foreline, a cleaning cycle is performed to dissolve, or otherwise break apart, the depositions within the foreline and downstream equipment. Conventionally, a cleaning cycle includes the use of excited cleaning gases within the foreline. However, it is difficult to maintain the excited state of the cleaning gases within the foreline. As the excitation state of the cleaning gases diminishes, so does the effectiveness of the cleaning cycle, resulting in inefficient deposition removal within the foreline and downstream equipment.

Thus, there is a need to improve cleaning of the foreline.

### SUMMARY

A component, system, and method for improved foreline and component cleaning are disclosed herein. In one example, a processing chamber component includes a foreline having a circular cross sectional shape and an inner surface. The foreline is constructed from stainless steel. The foreline further includes a first portion having a first end configured to couple to a processing chamber, a second portion having a second end configured to couple to a valve, and a coating disposed on the inner surface of the foreline. The first end includes a first flange. The second end includes a second flange. The first portion and the second portion are coupled together. The coating has a thickness of about 150 nanometer to about 525 nanometer.

In another example, a processing system includes a processing chamber, a foreline having a circular cross sectional shape and an inner surface, and a valve. The foreline is constructed from stainless steel. The foreline further includes a first portion having a first end configured to couple to a processing chamber, a second portion having a second end configured to couple to a valve, and a coating disposed on the inner surface of the foreline. The first end includes a first flange. The second end includes a second flange. The first portion and the second portion are coupled together. The coating has a thickness of about 150 nanometer to about 525 nanometer. The valve directly coupled to the second flange.

In another example, a method of cleaning a processing system comprises pumping a carbon containing gas out from a processing chamber and into a foreline, generate radicals from a cleaning gas and flow the radicals into the foreline, and etching deposits as the radicals flow through the foreline. The foreline has a coating comprising aluminum oxide and has a coating thickness of about 150 nanometer to about 525 nanometer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope and may admit to other equally effective embodiments.

FIG. 1 is a cross-sectional schematic view of an exemplary plasma processing chamber, according to certain aspects of the present disclosure.

FIG. 2 is a cross-sectional schematic view of the foreline coupled to the throttle valve, according to certain aspects of the present disclosure.

FIG. 3 is a schematic side view of the foreline, according to certain aspects of the present disclosure.

FIG. 4 is a method of a cleaning a processing system, according to certain aspects of the present disclosure.

To facilitate understanding, identical reference numerals have been used, where possible, to designate identical elements that are common to the figures. It is contemplated that elements and features of one embodiment may be beneficially incorporated in other embodiments without further recitation.

Many of the details, dimensions, angles, and other features shown in the figures are merely illustrative of particular implementations. Accordingly, other implementations can have other details, components, dimensions, angles, and features without departing from the spirit or scope of the present disclosure. In addition, further implementations of the disclosure can be practiced without several of the details described below.

### DETAILED DESCRIPTION

The present disclosure is directed towards a system for improved foreline cleaning for a processing system. It has been found that foreline cleaning using the disclosed technology improves the removal of undesired depositions within or on chamber foreline components, such as a valve. For example, the techniques described herein increase the duration of the energization state of cleaning gases, thus enabling more effective cleaning within the chamber foreline.

The present disclosure will elaborate on a coating used within the foreline that lengthens the lifespan of the cleaning gases for improved foreline cleaning of undesired depositions and reduce the sticking coefficient of the foreline inner surface. In some embodiments, the coating advantageously results in more uniform removal of the undesired depositions within the foreline and from downstream components during a cleaning process. In some embodiments, the coating may also advantageously result in a decreased tendency for undesired depositions from processing by-products to adhere to the interior surfaces of the foreline and downstream components during processing, thereby reducing the amount of undesired depositions needing to subsequently be removed in the cleaning. The more effective cleaning of the foreline results in a reduction in the duration of cleaning operation, the frequency of cleaning cycles, process control drift, equipment/component damage, and product waste, while improving operator safety, increasing product yield, increasing efficiency of processing, and lowering the cost of overall ownership.

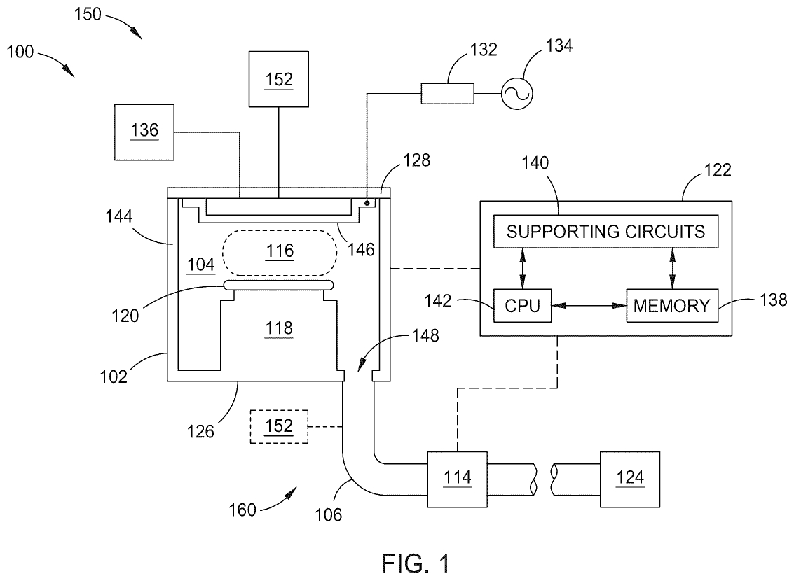

FIG. 1 is a cross-sectional schematic view of an exemplary processing system 150. The processing system 150 includes a plasma processing chamber 100, a controller 122 and an exhaust system 160. The processing system 150 is configured to effectively improve cleanliness of a foreline 106 and other components that couple the processing chamber 100 to the exhaust system 160, enabling the advantages described above. In some embodiments, the processing chamber 100 is a vacuum processing chamber, such as a deposition chamber, an ion implant chamber, an etch reactor chamber, a plasma treatment chamber, and an atomic layer deposition chamber, among others. Representative deposition chambers include plasma enhanced chemical vapor deposition (PECVD) chambers, chemical vapor deposition (CVD) chambers, and physical vapor deposition (PVD) chambers, among others. In the example depicted in FIG. 1, the processing chamber 100 is a PECVD chamber.

The processing chamber 100 includes a chamber body 102 having chamber sidewalls 144, a chamber bottom 126, and a removably coupled lid 128 that enclose an inner volume 104. In some embodiments, the chamber lid 128 is coupled to a gas panel 136. The gas panel 136 provides gases, such as processing and/or cleaning gases, to the inner volume 104 through a showerhead 146 that is coupled to a bottom of the chamber lid 128. The showerhead 146 is also coupled to a radio frequency (RF) RF power supply 134. The RF power supply 134 provides RF power through an RF matching circuit 132 and to the showerhead 146. RF power provided to the showerhead 146 from the RF power supply 134 energizes the gases within the inner volume 104 for processing substrates within the processing chamber 100 and/or to clean the interior of the processing chamber 100. In some embodiments, cleaning gases may optionally be provided to the inner volume 104 of the processing chamber 100 and/or directly to the foreline 106 via a remote plasma source (RPS) 152. In some embodiments, the energized showerhead 146 excites the gases within the inner volume 104 to create a plasma 116. Process gases, along with any processing by-products, are removed from the inner volume 104 through an exhaust port 148 formed in the chamber sidewalls 144, or chamber bottom 126, of the chamber body 102. The exhaust port 148 is coupled to the exhaust system 160 via the foreline 106, which may include further valves utilized to control the vacuum levels within the inner volume 104. The exhaust system 160 may be coupled to a vacuum pump 124.

A substrate support assembly 118 is disposed within the inner volume 104 of the chamber body 102. The substrate support assembly 118 is configured to receive, support, and process a substrate 120 thereon.

The gas panel 136 may provide various types of gases to the inner volume 104 of the chamber body 102. The gas panel 136 is coupled to a processing gas supply used to process the substrate 120 in the inner volume 104 of the plasma processing chamber 100. The gas panel 136 may also be coupled to a cleaning gas supply (not shown) used to perform a cleaning cycle within the processing chamber 100. In one example, the gas panel 136 is configured to supply a carbon containing deposition precursor utilized to deposit a carbon containing film on the substrate 120 within the processing chamber 100. In another example, the gas panel 136 provides a cleaning gas for forming oxygen radicals for reacting with deposited carbon by-products to clean the processing chamber 100, the foreline 106, and any downstream components.

A controller 122 is configured to receive data or input from sensor readings from a plurality of sensors (not shown) and send or output instructions to various process chamber components or equipment. The controller 122 can monitor, estimate an optimized parameter, adjust an initiated operation, generate an alert on a display, halt an operation, initiate a chamber downtime period, delay a subsequent iteration of an operation, initiate a cleaning operation, halt a cleaning operation, adjust a heating power, and/or otherwise adjust the process recipe. The controller 122 includes a central processing unit (“CPU”) 142 (e.g., a processor), a memory 138 containing instructions, and support circuits 140 for the CPU 142. The controller 190 controls various items directly, or via other computers and/or controllers. In one or more embodiments, the controller 122 is communicatively coupled to at least a throttle valve 114. The memory 138 can contain instructions, that when executed by the CPU 142, causes the processing system 150 to perform deposition and/or cleaning operations, such as later described below.

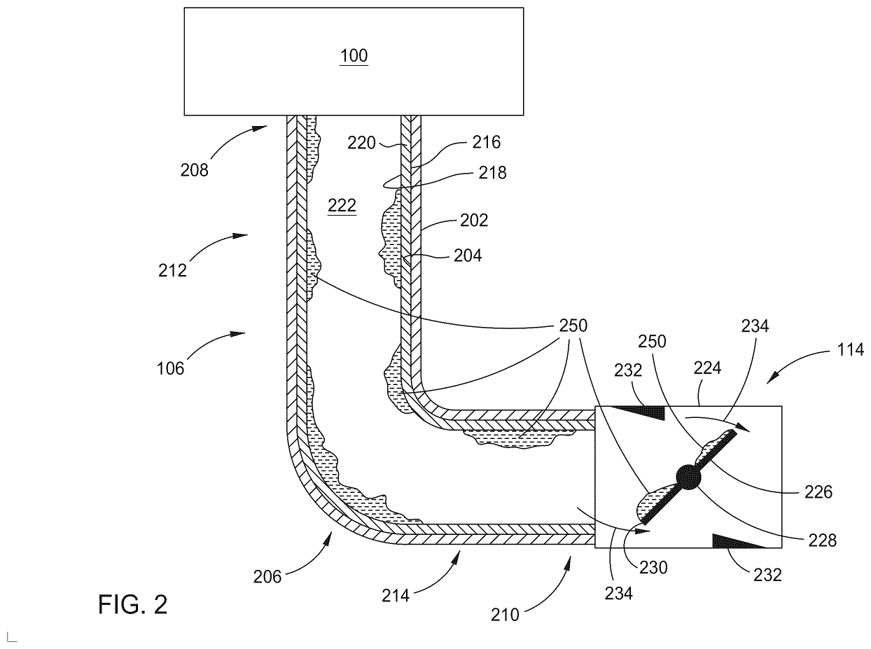

FIG. 2 is a cross-sectional schematic view of the foreline 106 extending from a portion of the processing chamber 100 and coupled to the throttle valve 114.

The foreline 106 is coupled to the processing chamber 100 at a foreline connection 208. The foreline 106 is coupled to the throttle valve 114 at a foreline connection 210. The foreline connections 208, 210 may be fastened to their adjacent components by, for example, flange couplers including bolts, compression clamps, or the like, or welds including butt, lap, corner, tee, or edge joints and the like. In some embodiments, as illustrated in FIG. 2, the foreline 106 has a first portion 212 and a second portion 214 coupled by a bend 206. The first portion 212 is at least twice as long as the second portion 214. The bend 206 generally ranges between 60 and 120 degrees, such as 90 degrees, although other angles may be utilized. The first portion 212 terminates at the foreline connection 208, while the second portion 214 terminates at the foreline connection 210. In other embodiments, the foreline 106 may be oriented out of the chamber body 102 and be substantially horizontal or substantially vertical. The foreline 106 may be oriented in multiple manners and is not illustrated to be limiting in positioning.

In the example shown, the foreline 106 illustrated in FIG. 2 includes undesired deposits 250. In one example, the undesired deposits 250 are carbon deposits resulting from depositing carbon containing films on the substrate 120 using a hydrocarbon or carbon containing deposition gas provided from the gas panel 136. In certain embodiments, the carbon deposits 250 form along the interior surface of the foreline 106 as a temperature in the foreline 106 decreases along the first portion 212 and the second portion 214 during processing. For example, in a conventional foreline (e.g., uncoated foreline), a temperature of portions of the foreline during processing may vary such as increasing to about 235 degrees Celsius at the foreline connection 208 near the processing chamber 100. As the foreline 106 extends farther away from the processing chamber 100, temperatures of corresponding portions of the foreline during processing may in turn decrease to about 82 degrees Celsius as the foreline approaches the throttle valve 114. As carbon containing processing by-products exit the process chamber through the foreline, the decrease in temperature in the foreline causes the undesired carbon deposits to form along an interior surface of the foreline.

The foreline 106 may be constructed from stainless steel, such as 304 stainless steel, 316 stainless steel, and/or 316L stainless steel. Alternatively, the foreline 106 may be constructed from another suitable material. In some embodiments, the foreline 106 may be a pipe having a circular cross-sectional shape. In other embodiments, the foreline 106 may be a tube or various cross-sectional shapes including a triangle, oval, rectangle, pentagon, hexagon, or the like. The foreline 106 has an exterior surface 202 and an interior surface 204. In a conventional foreline 106, such as a stainless steel foreline, oxygen radicals from the cleaning gas needed for cleaning the foreline 106 may recombine with the interior stainless steel surface of the foreline 106 in an exothermic reaction. Even with a dedicated oxygen radical remote plasma source, such recombination of the oxygen radicals with the stainless steel surface inside the foreline 106 leads to a decrease in the available oxygen radicals to effectively clean the foreline 106 and/or the throttle valve 114. Furthermore, the exothermic reaction from the recombination of the oxygen radicals with the stainless steel surface of the foreline 106 may also cause temperature spikes in the foreline 106 that may damage and/or affect the long term reliability of certain components of the exhaust system 160, such as an O-ring or heater jacket for the foreline 106.

In some embodiments, a coating 220 is disposed on the interior surface 204 of the foreline 106. The coating 220 has an outer surface 216 disposed in contact with the interior surface 204 of the foreline 106, and an inner surface 218 exposed to a foreline inner volume 222 that runs end-to-end through the foreline 106. In certain embodiments, the coating 220 comprises a sticking coefficient property configured to reduce recombination of oxygen radicals flowing through the foreline 106 with the stainless steel interior surface 204 of the foreline 106. As mentioned above, the lower sticking coefficient of the coating 220 may also reduce the tendency for undesired carbon depositions from processing by-products to adhere to the coating 220 coating the interior surfaces of the foreline, thereby decreasing the overall amount of undesired deposit 250 that would have otherwise adhered to an uncoated, or bare, foreline interior surface 204.

In some embodiments, the coating 220 comprises aluminum oxide (“Al₂O₃”) having a sticking coefficient of about 0.0001. In other embodiments, the coating 220 comprises aluminum (“Al”) having a sticking coefficient of about 0.001. The sticking coefficient of aluminum oxide and aluminum are both correspondingly lower than compared to stainless steel (“SST”) (e.g., uncoated foreline) having a sticking coefficient between about 0.1 to about 0.2. In some embodiments, the sticking coefficient of the coating 220 or the uncoated interior surface 204 of the foreline 106 may be dependent on the temperature and surface morphology. Without being bound by theory, it was observed that the lower sticking coefficient of aluminum oxide from the coating 220 provided reduced recombination of oxygen radicals in the foreline 106 thereby increasing oxygen radical supply and life in the foreline 106 during the cleaning process. In some embodiments, the coating 220 may comprise a thickness between about 100 nanometers (“nm”) and about 525 nm, such as between about 150 nm and about 475 nm thick, or between about 200 nm and about 425 nm thick. In some embodiments, the thickness of the coating 220 may improve adhesion between the interior surface 204 of the foreline 106 and the outer surface 216 of the coating 220. In some embodiments, the coating 220 is continuous within the foreline 106. In one embodiment, the thickness of the coating 220 is about 150 nm. In another embodiment, the thickness of the coating 220 is about 475 nm.

The throttle valve 114 is operable to control pressure within and/or flow exiting the processing chamber 100 during operation. As illustrated in FIG. 2, the throttle valve 114 comprises a valve body 224 having a rotatable disc 226 disposed therein. The disc 226 is coupled to a stem 228. The stem 228 is coupled to an actuator (not shown) that is actively controlled by the controller 122. The actuator rotates the stem 228 which in turn rotates the disc 226 within the valve body 224. The rotational orientation of the disc 226 controls the distance between an outer edge 230 of the disc 226 and wedges 232 disposed in the valve body 224 to control fluid passage through flow paths 234 of the throttle valve 114. To reduce the flow through the flow paths 234, the actuator rotates the stem 228 to abut the disc outer edge 230 of the disc 226 towards the wedge 232. As described, the throttle valve 114 may open, close, or modulate to regulate the flow or pressure within the processing chamber 100.

During deposition operations, the gas panel 136 may utilize carbon containing gases, such as acetylene, for patterning processes. These gases can cause undesired carbon deposits 250 in the foreline 106 and on the throttle valve 114 as illustrated in FIG. 2. As the deposits 250 build, the pressure or flow control of the throttle valve 114 is reduced leading to ineffective operation of the throttle valve 114. In other words, the undesired deposits 250 may reduce the area of the flow paths 234 and require the valve to rotate farther than programmed to allow the same amount of flow as compared to a clean disc 226. Similarly, the deposits 250 may reduce the foreline inner volume 222 leading to process drift and reduced accurate control. In some embodiments, the coating 220 of the foreline 106 may advantageously reduce oxygen radical recombination in the foreline 106 which in turn increases radical oxygen amount and life for cleaning the foreline 106. The decreased recombination of oxygen radicals in the foreline 106 may dramatically improve cleaning rate resulting in reduced cleaning cycle frequency and the time needed to clean the foreline 106. In some embodiments, the coating 220 of the foreline 106 may advantageously also reduce the tendency of undesired carbon deposits 250 to form within the foreline 106 due to the coating's low sticking coefficient as compared to an uncoated foreline 106 in which, in one embodiment, may therefore correspond to the higher sticking coefficient of stainless steel. This lower sticking coefficient results in increased oxygen radical life and supply in the inner foreline volume 222, as well as a lower tendency for formation of the carbon deposits 250 in the inner foreline volume 222 in general as compared to conventional uncoated forelines.

Cleaning cycles are periodically performed to etch away the deposits 250. The cleaning gases provided by the gas panel 136 (or alternatively the RPS 152) may be oxygen containing gases, such as oxygen gas (O₂). In some embodiments, the cleaning gases may alternatively or also comprise other non-oxygen containing gases, such as argon gas (Ar), nitrogen gas (N₂) and nitrogen trifluoride gas (NF₃). The cleaning gases are introduced to the processing chamber 100 from the gas panel 136 via the showerhead 146. A plasma 116 may be generated from the cleaning gases within the inner volume 104 to excite the oxygen containing gases. In some embodiments, the cleaning gases are excited external to the inner volume 104 via the RPS 152, and then introduced to the inner volume 104. Alternatively, the RPS 152 may be coupled directly to the foreline 106. The excited oxygen containing gases form oxygen radicals. The oxygen radicals effectively etch away the carbon deposits 250.

As the oxygen radicals flow out of the processing chamber 100 and into the foreline 106 for cleaning operations, the oxygen radicals react with and etch away the carbon deposits 250 within the foreline inner volume 222. As discussed above, the oxygen radicals are affected by the lower sticking coefficient of the foreline 106 leading to lower recombination rates due to the coating 220 now blocking the oxygen radicals from contact with the stainless steel interior surface 204 of the foreline 106. Thus, the presence of the coating 220 on the foreline 106 enables oxygen radicals to travel farther down the foreline 106, to the throttle valve 114, and beyond, thereby providing a faster and more thorough removal of unwanted carbon deposits 250.

As mentioned above, the recombination of the cleaning gas within the foreline 106 is an exothermic reaction that heats the foreline 106. In some embodiments, recombination of the cleaning gas within the foreline 106 can heat the foreline 106 to temperatures up to 250 degrees Celsius. In some embodiments, the heat produced from the recombination may exceed safety limits and/or damages adjacent components, such as heater jackets (not shown) at least partially surrounding the foreline 106. In those embodiments, the heat produced from the recombination reduces the long term reliability of the adjacent components. For example, the coated foreline 106 may operate about 170 degrees Celsius to about 180 degrees Celsius when deposition processes are being performed within the processing chamber 100. Advantageously, the reduced recombination of radicals provided by the coating 220 inside the foreline limits temperature rises of the coated foreline 106 during cleaning operations to between about 1 degree Celsius and about 10 degrees Celsius, such as about 2 degrees Celsius and about 9 degrees Celsius, such as about 3 degrees Celsius and about 8 degrees Celsius, such as about 4 degrees Celsius and about 6 degrees Celsius, such as about less than 10 degrees Celsius, and such about less than 5 degrees Celsius. Compared to the uncoated foreline, the coated foreline 106 experiences significantly less temperature variation that results in greater operator safety, increased adjacent component reliability, less process drift, and reduced frequency of foreline preventative maintenance.

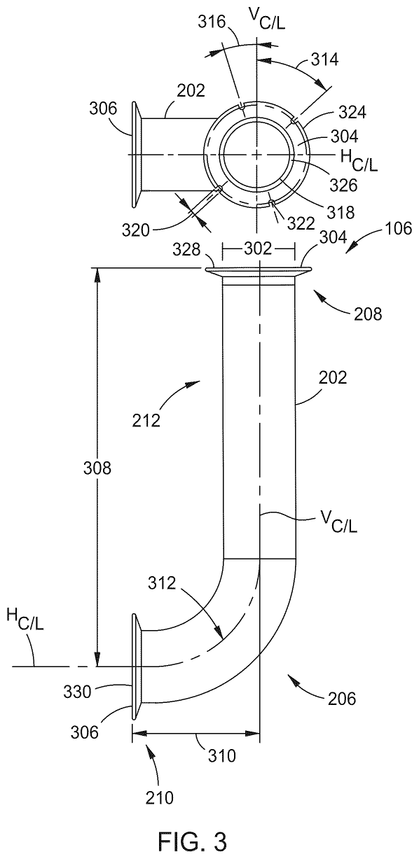

FIG. 3 is a schematic side view of the foreline 106 according to some embodiments. The foreline 106 comprises an exterior surface 202 on the first portion 212 coupled to the bend 206. The one end of the first portion 212 is coupled to foreline connection 208. The opposite end of the first portion 212 is coupled to an end of the bend 206. The opposite end of the bend 206 is coupled to foreline connection 210. In some embodiments, the bend 206 has a bending radius of about 2 inches (“in.”) to about 4 in. The bending radius dimensions are selected to enable the cleaning gas radicals to traverse the bend 206 without promoting recombination of the cleaning gas traveling across the bend 206. In other words, the bending radius is selected to reduce the amount of radical recombination, and consequentially heating of the foreline 106, as the cleaning gas traverses the bend 206 in the foreline 106.

In some embodiments, height 308 is about 11.00 in. to about 11.25 in. from a centerline (“H_{C/L}”) to a top surface 328 of the foreline connection 208. In some embodiments, the distance 310 between the top surface 330 of the foreline connection 208 to a centerline (“V_{C/L}”) is about 3.25 in. to about 3.75 in. In some embodiments, the foreline 106 may have an outer diameter 302 between about 1.75 in. and about 2.75 in., with a wall thickness between about 0.045 in. to 0.94 in. In such embodiments, the inner diameter 318 is about 2.0 in. to about 2.5 in. In another embodiment, the outer diameter 302 of the foreline is about 2 in. with a wall thickness of about 0.065 in. It is contemplated that the coated foreline may alternatively have different sizes and dimensions.

The foreline connection 208 comprises a flange 304. The flange 304 is configured to attach to the processing chamber 100. The outer diameter 324 is greater than the inner diameter 318. The inner diameter 318 is coupled a shelf 326 that is stepped down from the top surface 328 of the flange 304. The shelf 326 provides lateral stability between the foreline flange connection 208 and the processing chamber 100. In some embodiments, the flange 304 flares in an outward direction producing an angled foreline connection 208, as illustrated. The flange 304 has cutaways 322. There may a several cutaways 322 located about the perimeter of the flange 304. As illustrated, the flange 304 has four cutaways 322. In some embodiments, the cutaways 322 are bore holes with a diameter 320 of about 0.140 in. to about 0.160 in. In some embodiments, the cutaways 322 may have tangential cuts out to form the rectangular shape with semi-circular ends, as illustrated in FIG. 3. In some embodiments, the cutaways 322 are disposed at a first angle 314 of about 47 degrees to about 48 degrees from the V_{C/L}. In those embodiments, other cutaways 322 are disposed a second angle 316 in a direction opposite the V_{C/L} from the first angle 314, of about 17 degrees to about 18 degrees. In some embodiments, the cutaways 322 each have a corresponding cutaway 322 disposed across or about 180 degrees around the flange 304. The cutaways 322 are positioned on the flange 304 to provide support and stability between the foreline connection 208 and the processing chamber 100.

The foreline connection 210 comprises a flange 306 having top surface 330. The flange 306 is configured to attach to the throttle valve 114. In some embodiments, the flange 306 flares in an outward direction producing an angled foreline connection 210, as illustrated. Similar to the flange 304, the flange 306 may have cutaways similar to cutaways 322.

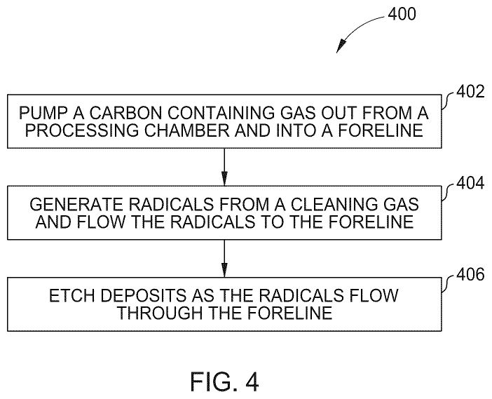

FIG. 4 is a method of a cleaning a processing system. The method 400 comprises operation 402, operation 404, and operation 406, and operation 408. The method 400 may be used to advantageously clean the processing system, particularly the foreline 106 and the throttle valve 114.

The method 400 begins at operation 402 by pumping a carbon containing gas out from a processing chamber 100 and into a foreline 106. In one example, the carbon containing gas is utilized to deposit a carbon containing film on a substrate 120 disposed in the processing chamber 100. In another example, the gases may contain compounds from a dielectric deposition process or from a metal deposition process. Embodiments of compounds present in the deposition gases include silicon-containing materials, chlorinated hydrocarbons (CHCs), hydrofluorocarbons (HFCs), chlorofluorocarbons (CFCs), or other compounds.

After the substrate 120 is removed from the processing chamber 100 after operation 402, the method 400 proceeds to operation 404. At operation 404, radicals are generated from a cleaning gas and delivered to the foreline 106. Stated in a different manner, the cleaning gas radicals are flowed into the coated foreline 106. As discussed above, the cleaning gas radicals provided to the foreline 106 flow into contact with the exhaust system 160. The radicals may be generated within the processing chamber 100, for example, by forming a plasma 116 from a cleaning gas, or provided to the processing chamber 100 via RPS 152. Alternatively, radicals generated from the cleaning gas may be formed within the foreline 106, or in another alternative, be provided to the foreline 106 from the remote plasma source directly while by-passing the processing chamber. As discussed above, cleaning gases may be provided to the inner volume 104 of the processing chamber 100 through gas conduits coupled between the gas panel 136 and the showerhead 146. The cleaning gas may be energized to create plasma 116 from the RF power supply 134. The plasma 116 creates radicals from the cleaning gases.

At operation 406, the cleaning gas radicals etch away deposits 250 as the radicals traverse the foreline 106 and flow through the throttle valve 114. The coating 220 disposed along the interior surface 204 of the foreline 106 reduces the tendency of carbon deposits to adhere to the inner surface 218 of the coating 220. By reducing the adhesion of the radicals to the coating 220, the radicals may travel farther down the foreline 106 and through throttle valve 114 thus providing improved cleaning of the foreline 106 and throttle valve 114. Additionally, the coating 220 reduces the tendency of deposits 250 to adhere to the foreline 106, thereby extending the mean time between cleaning operations. In some embodiments, the coating 220 may also be present on the various components of the throttle valve 114 to reduce the tendency of deposits 250 from adhering to the throttle valve 114.

As discussed above, the recombination of the radicals may be an exothermic reaction. Uncoated forelines experience hot zones in areas of the foreline such as the first portion 212 of foreline 106 that may cause adjacent component damage, such as a heater jacket, and/or operator injuries. The coating 220 advantageously reduces temperature variations in the foreline 106 between a processing operation and a cleaning operation within 20 degrees Celsius, such as about less than 10 degrees Celsius, such as about less than 5 degrees Celsius. Stated differently, the coated foreline 106 exhibits no undesired excessive temperature rises between a processing operation and a cleaning operation. In some embodiments, the coating 220 enables a substantially stable temperature profile in the foreline 106. Compared to the uncoated foreline, the coated foreline 106 experiences significantly less temperature variation that results in greater operator safety, increased adjacent component reliability, and reduced frequency of foreline 106 failure.

The benefits of the present disclosure improve cleaning of the foreline 106 and throttle valve 114 by providing a coating along the interior surface 204 of the foreline 106. As discussed above, the coating 220 inhibits the recombination of cleaning gas radicals within the foreline, advantageously allowing increased supply of the radicals to reach the throttle valve 114 for effective and efficient cleaning of undesired deposits 250. In some embodiments, the coating 220 also enables the improved foreline 106 to remain cleaner during normal operation of the processing chamber by decreasing a tendency for undesired deposits 250 to form on the coating 220, resulting in faster foreline cleans, reduced preventative maintenance, reduced process drift, increased process yield, and lowered cost of ownership.

While the foregoing is directed to embodiments of the present disclosure, other and further embodiments of the disclosure may be devised without departing from the basic scope thereof, and the scope thereof is determined by the claims that follow.

What is claimed is:

1. A processing chamber component, comprising:
a foreline having a circular cross sectional shape and an inner surface, the foreline constructed from stainless steel, the foreline comprising:
a first portion having a first end configured to couple to a processing chamber, the first end comprising a first flange;
a second portion having a second end configured to couple to a valve, the second end comprising a second flange, the first portion and the second portion fluidly coupled together; and
a coating disposed on the inner surface of the foreline, the coating having a thickness between about 125 nanometers and about 525 nanometers.

2. The processing chamber component of claim 1, wherein the coating comprises aluminum or aluminum oxide.

3. The processing chamber component of claim 1, wherein the coating comprises a thickness between about 200 nanometer and about 475 nanometer.

4. The processing chamber component of claim 1, wherein the foreline comprises stainless steel.

5. The processing chamber component of claim 1, wherein the first portion and the second portion are fluidly coupled together at a bend.

6. The processing chamber component of claim 1, wherein the foreline comprises a wall thickness between about 0.045 inches to about 0.94 inches.

7. The processing chamber component of claim 1, wherein the first flange has a plurality of cutaways disposed around a perimeter of the first flange, each of the plurality of cutaways having another cutaway directly across the first flange.

8. The processing chamber component of claim 1, wherein the first portion is at least twice as long as the second portion, the first and second portions coupled by a bend.

9. A processing system, comprising:
a processing chamber;
a foreline having a circular cross sectional shape and an inner surface, the foreline constructed from stainless steel, the foreline comprising:
a first portion having a first end configured to couple to a processing chamber, the first end comprising a first flange;
a second portion having a second end configured to couple to a valve, the second end comprising a second flange, the first portion and the second portion fluidly coupled together; and
a coating disposed on the inner surface of the foreline, the coating comprising a thickness between about 150 nanometers and about 525 nanometer; and
a valve directly coupled to the second flange.

10. The processing system of claim 9, wherein the coating comprises aluminum or aluminum oxide.

11. The processing system of claim 9, wherein the coating comprises a thickness between about 200 nanometers and about 475 nanometers.

12. The processing system of claim 9, wherein the foreline comprises stainless steel.

13. The processing system of claim 9, wherein the first flange has a plurality of cutaways disposed around a perimeter of the first flange, each of the plurality of cutaways having another cutaway directly across the first flange.

14. The processing system of claim 9, wherein the valve is a butterfly valve.

15. The processing system of claim 9, further comprising a heater jacket at least partially surrounding the foreline.

16. A method of cleaning a processing system, comprising:
pumping a carbon containing gas out from a processing chamber and into a foreline, the foreline having a coating comprising aluminum oxide and having a coating thickness between about 150 nanometers and about 525 nanometers;
generating radicals from a cleaning gas and flowing the radicals into the foreline; and
etching deposits as radicals flow through the foreline.

17. The method of claim 16, wherein the cleaning gas contains oxygen.

18. The method of claim 16, wherein the foreline comprises stainless steel.

19. The method of claim 16, further comprising removing a substrate from the processing system after pumping the carbon containing gas into the foreline.

20. The method of claim 16, wherein the coating comprises aluminum or aluminum oxide, and a thickness of the coating is between about 200 nanometers and about 475 nanometers.
